(19) United States
(12) Patent Application Publication
(10) Pub. No.: US 2015/0372134 A1
(43) Pub. Date: Dec. 24, 2015

(54) SEMICONDUCTOR STRUCTURE AND METHOD FOR MANUFACTURING THE SAME

(71) Applicant: Macronix International Co., Ltd., Hsinchu (TW)

(72) Inventor: Wing-Chor Chan, Hsinchu City (TW)

(21) Appl. No.: 14/311,414

(22) Filed: Jun. 23, 2014

(51) Int. Cl. H01L 29/78; H01L 29/66; H01L 29/10; H01L 27/02

(52) U.S. Cl. CPC H01L 29/7817; H01L 27/0266; H01L 29/66681; H01L 29/1095

(57) ABSTRACT

A semiconductor structure and a method for manufacturing the same are disclosed. The semiconductor structure comprises a substrate, a first well formed in the substrate, a first heavily doped region formed in the first well, a second heavily doped region formed in the substrate and separated apart from the first well, a second well formed in the substrate and under the second heavily doped region, a gate dielectric formed on the substrate between the first heavily doped region and the second heavily doped region, and a gate electrode formed on the gate dielectric. The gate dielectric has a substantially uniform thickness across at least a portion extending from a side close to the second heavily doped region. The first well has a first type of doping. The first heavily doped region, the second heavily doped region and the second well have a second type of doping.

### BACKGROUND

1. Technical Field

The disclosure relates to a semiconductor structure and a method for manufacturing the same. More particularly, the disclosure relates to a semiconductor structure comprising an electrostatic discharge (ESD) protection device and a method for manufacturing the same.

2. Description of the Related Art

Electrostatic discharge (ESD) may cause damage to sensitive electronic devices. As such, ESD protection devices are typically provided in the semiconductor structures. High voltage electronic devices, such as extended drain MOSFET (EDMOSFET), lateral double-diffused MOSFET (LDMOSFET), devices applying the reduced surface field (RESURF) technique, and the like, may be used as the ESD protection devices.

The ESD protection performance of the high voltage electronic devices generally depends on the surface/lateral rules of the devices. However, the widths and the rules can not be increased due to the low on-state resistance requirement of the high voltage electronic devices.

While the low on-state resistance is required, it will lead to a current concentration on the surface or drain side during an ESD event. High current and dense electric field will cause a physical destruction of the surface junction.

High breakdown voltage, which is another important requirement of the high voltage electronic devices, is always higher than the operation voltage. Further, the trigger voltage of the ESD protection device is generally much higher than the breakdown voltage. As such, the devices to be protected may be damaged before the turn-on of the protection devices during an ESD event. The decrease of the trigger voltage of the ESD protection device is thus needed.

### SUMMARY

In this disclosure, a semiconductor structure, which comprises an improved ESD protection device, and a method for manufacturing the same are provided.

According to some embodiment, the semiconductor structure comprises a substrate, a first well, a first heavily doped region, a second heavily doped region, a second well, a gate dielectric and a gate electrode. The first well is formed in the substrate. The first well has a first type of doping. The first heavily doped region is formed in the first well. The first heavily doped region has a second type of doping. The second heavily doped region is formed in the substrate and separated apart from the first well. The second heavily doped region has the second type of doping. The second well is formed in the substrate and under the second heavily doped region. The second well has the second type of doping. The gate dielectric is formed on the substrate between the first heavily doped region and the second heavily doped region and at least partly formed on the first well. The gate dielectric has a substantially uniform thickness across at least a portion extending from a side close to the second heavily doped region. The gate electrode is formed on the gate dielectric.

According to some embodiment, the semiconductor structure comprises a substrate, a first well, a first heavily doped region, a first doped region, a second heavily doped region, a second well, a second doped region, a third heavily doped region, a gate dielectric and a gate electrode. The first well is formed in the substrate. The first well has a first type of doping. The first heavily doped region is formed in the first well. The first heavily doped region has a second type of doping. The first doped region is formed in the first well adjacent to the first heavily doped region. The first doped region has the first type of doping. The second heavily doped region is formed in the substrate and separated apart from the first well. The second heavily doped region has the second type of doping. The second well is formed in the substrate and under the second heavily doped region. The second well has the second type of doping. The second doped region extends along a top surface of the substrate from the second heavily doped region and the second well. The second doped region has the second type of doping. The third heavily doped region is formed in the first heavily doped region. The third heavily doped region has the first type of doping. The gate dielectric is formed on the substrate between the first heavily doped region and the second heavily doped region and at least partly formed on the first well. The gate dielectric has a substantially uniform thickness across at least a portion extending from a side close to the second heavily doped region. The portion of the gate dielectric having the substantially uniform thickness is formed on the second doped region. The gate electrode is formed on the gate dielectric.

According to some embodiment, the method for manufacturing the semiconductor structure comprises the following steps. First, a substrate is provided. A first well having a first type of doping is formed in the substrate. A first heavily doped region having a second type of doping is formed in the first well. A second heavily doped region having the second type of doping is formed in the substrate and apart from the first well. A second well having the second type of doping is formed in the substrate and under the second heavily doped region. A gate dielectric is formed on the substrate between the first heavily doped region and the second heavily doped region, and at least partly formed on the first well. The gate dielectric is formed to have a substantially uniform thickness across at least a portion extending from a side close to the second heavily doped region. After that, a gate electrode is formed on the gate dielectric.

### BRIEF DESCRIPTION OF THE DRAWINGS

FIG. 1 schematically shows a top view of a semiconductor structure according to one embodiment.

FIG. 2 schematically shows a cross-sectional view of a semiconductor structure according to one embodiment.

FIGS. 3-4 show characteristics of a semiconductor structure according to one example of the disclosure.

FIG. 5 shows characteristics of a semiconductor structure according to a comparative example.

FIG. 6 schematically shows a cross-sectional view of a semiconductor structure according to one embodiment.

FIG. 7 schematically shows a cross-sectional view of a semiconductor structure according to one embodiment.

FIG. 8 schematically shows a cross-sectional view of a semiconductor structure according to one embodiment.

FIG. 9 schematically shows a cross-sectional view of a semiconductor structure according to one embodiment.

FIG. 10 schematically shows a top view of a semiconductor structure according to one embodiment.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Now the description is directed to the semiconductor structure comprising the ESD protection device and the method for manufacturing the same. For clarity, some element may be enlarged in or omitted from the drawings. Similar elements will be indicated by similar reference numerals, while possible.

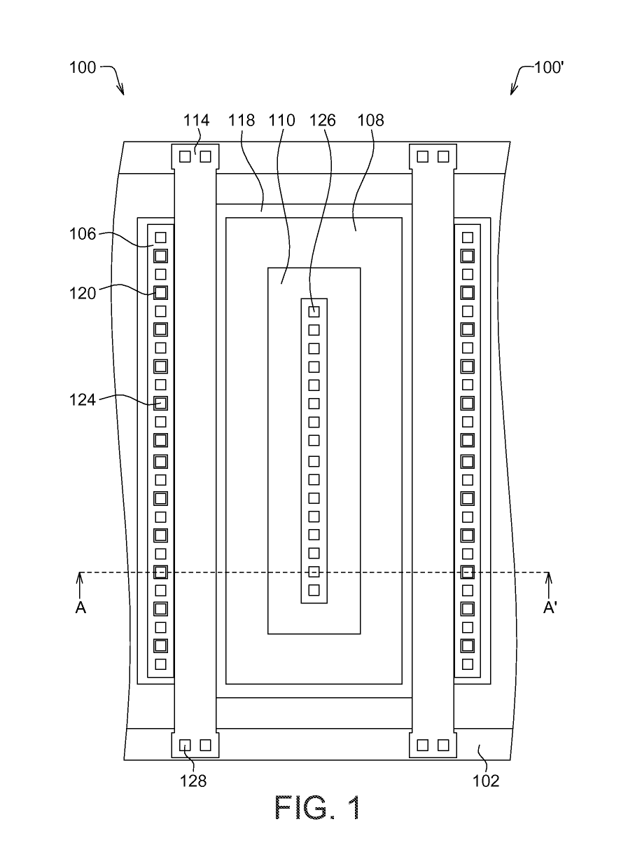

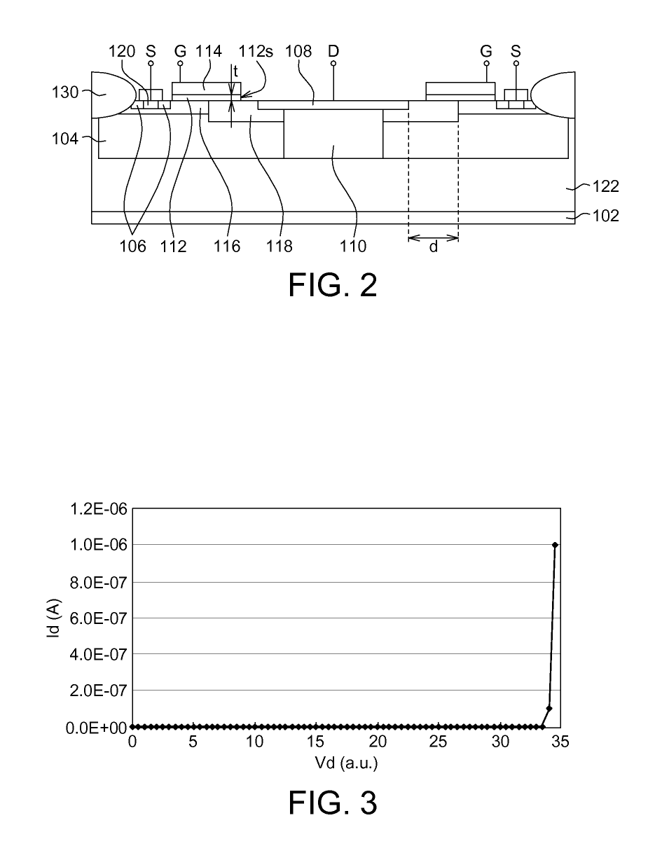

Referring to FIG. 1, a top view of a semiconductor structure according to one embodiment is shown. A cross section taken from line A-A′ in FIG. 1 may have a configuration as shown in FIG. 2.

The semiconductor structure comprises an ESD protection device 100 and a substrate 102. The substrate 102 may be a silicon substrate, a silicon on insulator (SOI) substrate or the like, and optionally comprise layer(s) formed thereon. The substrate 102 may be manufactured by epitaxial or non-epitaxial method. The substrate 102 may has p type of doping or n type of doping. Here, the substrate 102 has p type of doping for example.

In FIG. 2, the ESD protection device 100 is exemplarily illustrated to have the EDMOSFET configuration. However, the embodiment is not limited thereto, for example, the ESD protection device 100 may have a LDMOSFET configuration. The ESD protection device 100 comprises a first well 104, a first heavily doped region 106, a second heavily doped region 108, a second well 110, a gate dielectric 112 and a gate electrode 114. The first well 104 is formed in the substrate 102. The first well 104 has a first type of doping. The first heavily doped region 106 is formed in the first well 104. The first heavily doped region 106 has a second type of doping. The second heavily doped region 108 is formed in the substrate 102 and separated apart from the first well 104. The second heavily doped region 108 has the second type of doping. In some examples, the first heavily doped region 106 is connected to source, and the second heavily doped region 108 is connected to drain. The distance d from the edge of the second heavily doped region 108 to the gate may be used to adjust the breakdown voltage and trigger voltage of the ESD protection device 100, for example, adjusting the breakdown voltage in a range from 18 V to 50 V. More specifically, the decrease of distance d may lead to a decrease in breakdown voltage and trigger voltage. The second well 110 is formed in the substrate 102 and under the second heavily doped region 108. The second well 110 has the second type of doping. The disposition of the second well 110 forces the current down away from the surface. As such, the ESD protection performance may be improved. In this embodiment, the first type of doping may be p type of doping, and the second type of doping may be n type of doping. In an alternative embodiment, the first type of doping may be n type of doping, and the second type of doping may be p type of doping.

The gate dielectric 112 is formed on the substrate 102 between the first heavily doped region 106 and the second heavily doped region 108, and at least partly formed on the first well 104. The gate dielectric 112 is formed to have a substantially uniform thickness t across at least a portion extending from a side 112s close to the second heavily doped region 108. In this embodiment, the gate dielectric 112 having the substantially uniform thickness t across the whole gate dielectric 112. In some examples, the thickness t is in a range from about 200 Å to about 1000 Å. Rather than the field oxide widely used in the conventional EDMOSFET as the gate dielectric, in this embodiment, a dielectric layer, such as an oxide layer, formed on the substrate 102 may be used as the gate dielectric 112. As such, the thickness of the gate dielectric decreases considerably, for example, from about 3000 Å to about 200 to 1000 Å. Thus, the ESD protection performance can be improved. The gate electrode 114 is formed on the gate dielectric 112.

The ESD protection device 100 may further comprise a first doped region 116 formed in the first well 104 adjacent to the first heavily doped region 106. The first doped region 116 has the first type of doping. The first doped region 116 may be a field implantation region. In an alternative embodiment, the first doped region 116 may be formed as a body implantation, and the ESD protection device 100 has the LDMOSFET configuration.

The ESD protection device 100 may further comprise a second doped region 118 extending along a top surface of the substrate 102 from the second heavily doped region 108 and the second well 110. The second doped region 118 has the second type of doping. The portion of the gate dielectric 112 having the substantially uniform thickness t is formed on the second doped region 118. The second doped region 118 may be a drift region. The breakdown voltage and the trigger voltage may be adjusted by the length of the drift region.

The ESD protection device 100 may further comprise a third heavily doped region 120 formed in the first heavily doped region 106. The third heavily doped region 120 has the first type of doping. Such disposition may improve the ESD protection performance.

The ESD protection device 100 may further comprise a deep well 122 formed in the substrate 102. The deep well 122 has the second type of doping. The first well 104 and the second well 110 are formed in the deep well 122.

As shown in FIG. 1, another ESD protection device 100′ may be formed symmetrically to the ESD protection device 100. Further, the ESD protection device 100 may share the second heavily doped region 108, the second well 110 and the deep well 122 with the ESD protection device 100′. The symmetrical ESD protection devices 100 and 100′ work together for ESD protection.

The semiconductor structure may further comprise source contacts 124, drain contacts 126 and gate contacts 128. The semiconductor structure may further comprise field oxides 130 for isolation, as shown in FIG. 2. However, the embodiment is not limited thereto, any isolation structure being known in the art may be used, such as shallow trench isolation (STI).

Here, the semiconductor structure may be manufactured from any standard process, such as single poly process or double poly process, or epitaxial process or non-epitaxial process, without an additional mask.

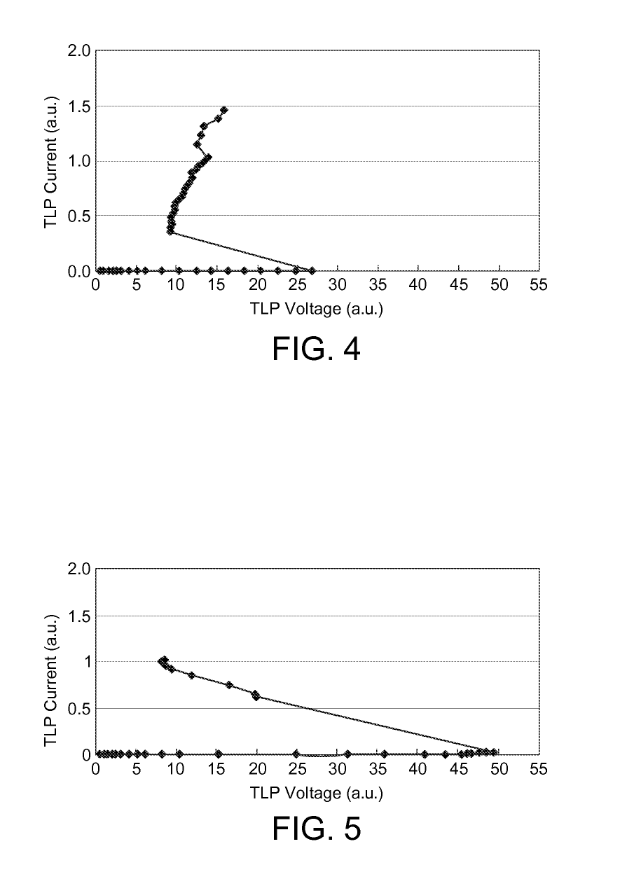

Referring to FIGS. 3-4, characteristics of a semiconductor structure according to one example of the disclosure are shown. As shown in FIG. 3, the breakdown voltage of a semiconductor structure comprising an ESD protection device according to one example of the disclosure is about 33.5 V. As shown in FIG. 4, the trigger voltage of the ESD protection device is about 27 V, lower than the breakdown voltage. Compared to the conventional ESD protection device with the same gate-to-drain distance (d value), of which the characteristics are shown in FIG. 5, the TLP current according to the example of this disclosure improves as 1.5 times, the holding voltage keeps almost the same, the breakdown voltage is close to that of the comparative example, and and the trigger voltage decreases considerably.

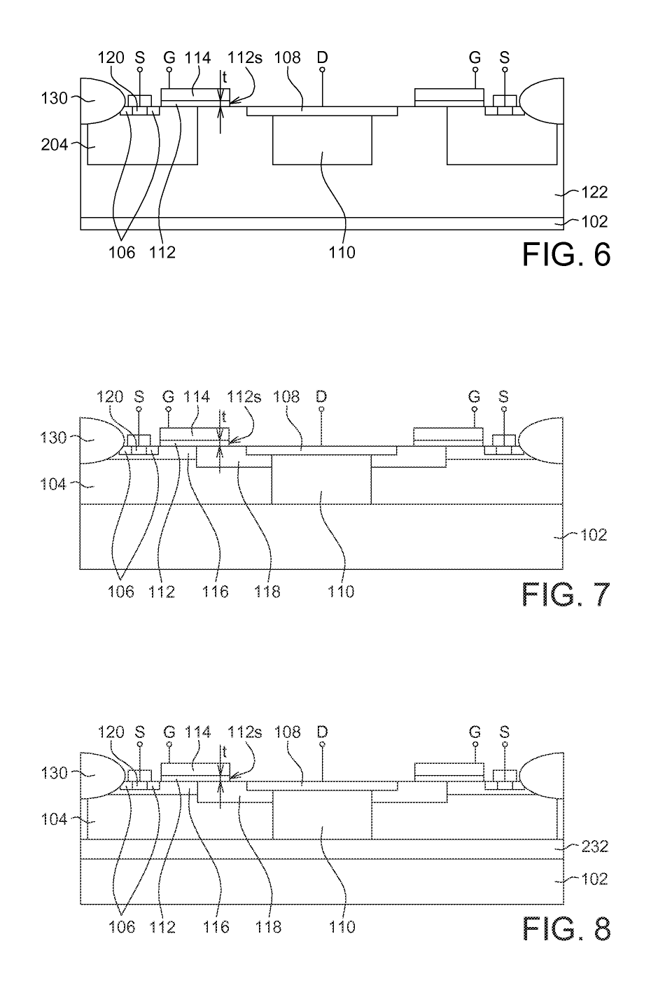

Now referring to FIG. 6, a semiconductor structure according to another embodiment is shown in a cross-sectional view. In this embodiment, the first doped region 116 and the second doped region 118 are not included in the semiconductor structure. The doped region of the first well 204 decreases, and the first well 204 is separated from the second well 110.

In another embodiment, as shown in FIG. 7, the deep well 122 may be removed from the semiconductor structure. As such, no isolation is provided at the bottoms of the first well 104 and the second well 110.

In another embodiment, as shown in FIG. 8, a buried layer 232 is formed in the substrate 102 and under the first well 104 and the second well 110. The buried layer 232 has the second type of doping. The buried layer 232, instead of the deep well 122, provides isolation to the semiconductor structure.

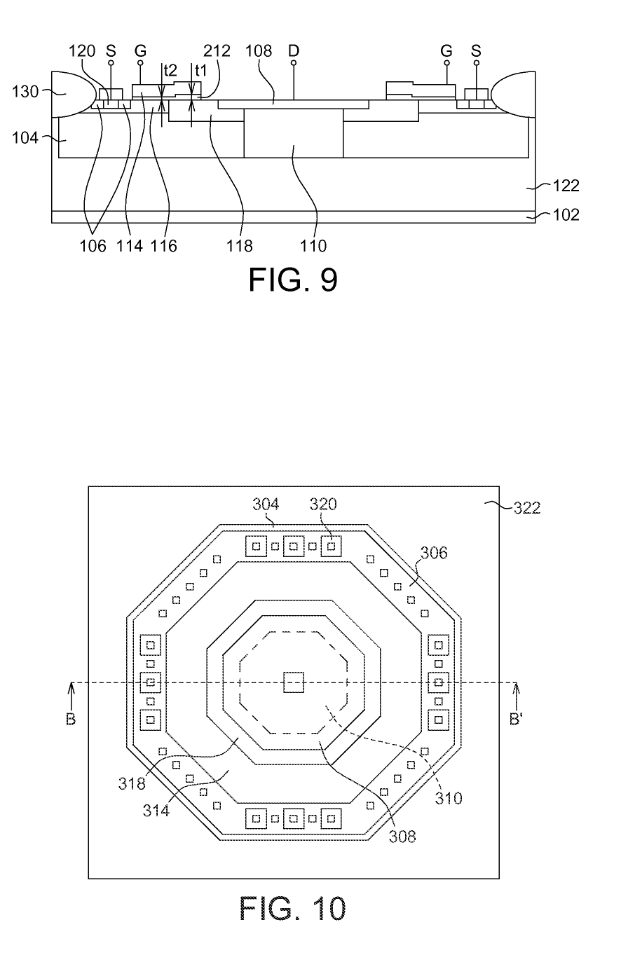

In another embodiment, as shown in FIG. 9, the gate dielectric 212 may have two different thickness t1 and t2. The thickness t2 of the gate dielectric 212 at a portion directly on the channel region, which is located in the first doped region 116 in FIG. 9, is smaller than the thickness t1 at the other portion. In other words, the gate dielectric 212 is thinner at the portion directly on the channel region. As such, the turn-on voltage can be decreased.

Referring to FIG. 10, a semiconductor structure according to another embodiment is shown in a top view. In this embodiment, the semiconductor structure has an octagonal arrangement. Unlike the strip-shaped arrangement as shown in FIG. 1, the octagonal arrangement itself is symmetrical. As such, two symmetrically disposed ESD protection devices are unneeded. In FIG. 10, the first well 304, the first heavily doped region 306, the second heavily doped region 308, the second well 310, the gate electrode 314, the second doped region 318, the third heavily doped region 320 and the deep well 322 are shown. The cross section taken from line B-B′ in FIG. 10 may have a configuration as shown in any one of FIGS. 2 to 9.

While only the strip-shaped arrangement (FIG. 1) and the octagonal arrangement (FIG. 10) are shown, other arrangements may be used, such as rectangular arrangement, hexagonal arrangement, circular arrangement, square arrangement or the like.

It will be apparent to those skilled in the art that various modifications and variations can be made to the disclosed embodiments. It is intended that the specification and examples be considered as exemplary only, with a true scope of the disclosure being indicated by the following claims and their equivalents.

1. A semiconductor structure, comprising:
a substrate;
a first well formed in the substrate, the first well having a first type of doping;
a first heavily doped region formed in the first well, the first heavily doped region having a second type of doping;
a second heavily doped region formed in the substrate and separated apart from the first well, the second heavily doped region having the second type of doping;
a second well formed in the substrate and under the second heavily doped region, the second well having the second type of doping;
a gate dielectric formed on the substrate between the first heavily doped region and the second heavily doped region and at least partly formed on the first well, the gate dielectric having a substantially uniform thickness across at least a portion extending from a side close to the second heavily doped region; and
a gate electrode formed on the gate dielectric.

2. The semiconductor structure according to claim 1, further comprising:
a first doped region formed in the first well adjacent to the first heavily doped region, the first doped region having the first type of doping.

3. The semiconductor structure according to claim 1, further comprising:
a second doped region extending along a top surface of the substrate from the second heavily doped region and the second well, the second doped region having the second type of doping, wherein the portion of the gate dielectric having the substantially uniform thickness is formed on the second doped region.

4. The semiconductor structure according to claim 1, further comprising:
a third heavily doped region formed in the first heavily doped region, the third heavily doped region having the first type of doping.

5. The semiconductor structure according to claim 1, further comprising:
a deep well formed in the substrate, the deep well having the second type of doping, wherein the first well and the second well are formed in the deep well.

6. The semiconductor structure according to claim 1, further comprising:
a buried layer formed in the substrate and under the first well and the second well, the buried layer having the second type of doping.

7. The semiconductor structure according to claim 1, wherein the gate dielectric having the substantially uniform thickness across the whole gate dielectric.

8. The semiconductor structure according to claim 7, wherein the substantially uniform thickness is in a range from 200 Å to 1000 Å.

9. The semiconductor structure according to claim 1, further comprising:
an electrostatic discharge (ESD) protection device comprising the first well, the first heavily doped region, the second heavily doped region, the second well, the gate dielectric and the gate electrode.

10. The semiconductor structure according to claim 9, further comprising:
another ESD protection device formed symmetrically to the ESD protection device, wherein the ESD protection device shares the second heavily doped region and the second well with the another ESD protection device.

11. A semiconductor structure, comprising:
a substrate;
a first well formed in the substrate, the first well having a first type of doping;
a first heavily doped region formed in the first well, the first heavily doped region having a second type of doping;
a first doped region formed in the first well adjacent to the first heavily doped region, the first doped region having the first type of doping;
a second heavily doped region formed in the substrate and separated apart from the first well, the second heavily doped region having the second type of doping;
a second well formed in the substrate and under the second heavily doped region, the second well having the second type of doping;
a second doped region extending along a top surface of the substrate from the second heavily doped region and the second well, the second doped region having the second type of doping;
a third heavily doped region formed in the first heavily doped region, the third heavily doped region having the first type of doping;
a gate dielectric formed on the substrate between the first heavily doped region and the second heavily doped region and at least partly formed on the first well, the gate dielectric having a substantially uniform thickness across at least a portion extending from a side close to the second heavily doped region, wherein the portion of the gate dielectric having the substantially uniform thickness is formed on the second doped region; and
a gate electrode formed on the gate dielectric.

12. A method for manufacturing a semiconductor structure, comprising:
providing a substrate;
forming a first well having a first type of doping in the substrate;
forming a first heavily doped region having a second type of doping in the first well;
forming a second heavily doped region having the second type of doping in the substrate and apart from the first well;
forming a second well having the second type of doping in the substrate and under the second heavily doped region;
forming a gate dielectric on the substrate between the first heavily doped region and the second heavily doped region and at least partly on the first well, the gate dielectric being formed to have a substantially uniform thickness across at least a portion extending from a side close to the second heavily doped region; and
forming a gate electrode on the gate dielectric.

13. The method according to claim 12, further comprising:
forming a first doped region having the first type of doping in the first well adjacent to the first heavily doped region.

14. The method according to claim 12, further comprising:
forming a second doped region having the second type of doping extending along a top surface of the substrate from the second heavily doped region and the second well, wherein the portion of the gate dielectric having the substantially uniform thickness is formed on the second doped region.

15. The method according to claim 12, further comprising:
forming a third heavily doped region having the first type of doping in the first heavily doped region.

16. The method according to claim 12, further comprising:
forming a deep well having the second type of doping in the substrate, wherein the first well and the second well are formed in the deep well.

17. The method according to claim 12, further comprising:
forming a buried layer having the second type of doping in the substrate and under the first well and the second well.

18. The method according to claim 12, wherein the gate dielectric having the substantially uniform thickness across the whole gate dielectric.

19. The method according to claim 18, wherein the substantially uniform thickness is in a range from 500 Å to 600 Å.

20. The method according to claim 12, further comprising:
forming an ESD protection device comprising the first well, the first heavily doped region, the second heavily doped region, the second well, the gate dielectric and the gate electrode; and
forming another ESD protection device symmetrical to the ESD protection device, wherein the ESD protection device shares the second heavily doped region and the second well with the another ESD protection device.
